(19) United States
(12) Patent Application Publication
(10) Pub. No.: US 2006/0290345 A1
(43) Pub. Date: Dec. 28, 2006

(54) Measuring cell holding mechanism and biosensor

(75) Inventor: Yoshiyuki Kunuki, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/475,091

(22) Filed: Jun. 27, 2006

(30) Foreign Application Priority Data
Jun. 27, 2005 (JP) 2005-187201

(51) Int. Cl. G01R 31/28

(52) U.S. Cl. 324/158.1

(57) ABSTRACT

A measuring cell holding mechanism, comprising a measuring cell which is configured to include a dielectric block in which a flat face on which a ligand to be attached is formed, and a flow path member which constitutes a flow path between it and this flat face; a dielectric block pressing member which presses the dielectric block from the flow path member side; and a flow path member pressing member which presses the flow path member from the side opposite from the side on which the dielectric block is disposed, with a pressing force smaller than that by the dielectric block pressing member.

### CROSS-REFERENCE TO RELATED APPLICATIONS

This application claims priority under 35USC 119 from Japanese Patent Application, insert identifying information for all JP priority application No. 2005-187201, the disclosure of which is incorporated by reference herein.

### BACKGROUND OF THE INVENTION

1. Field of the Invention

The present invention relates to a measuring cell holding mechanism which holds a measuring cell comprising a flow path for supplying an analyte solution containing an analyte to a ligand, in measuring position, and a biosensor comprising this measuring cell holding mechanism.

2. Description of the Related Art

Conventionally, a process in which a ligand is attached(immobilized) on a measuring cell; a flow path is configured in the portion where the ligand is attached; to this flow path, an analyte solution containing an analyte is supplied; and a light beam is irradiated from the side opposite from that of the flow path, whereby the interaction between the ligand and the analyte is measured has been carried out (referring to Japanese Patent Publication No. 3294605). Generally, for such a measurement, it is necessary to firmly fix the measuring cell such that it will not be displaced during measurement.

However, when supply of a liquid, such as an analyte solution, or the like, to the flow path is performed by directly accessing the flow path, the measuring cell tends to be easily displaced at the time of this access. Therefore, it is postulated that the measuring cell be pressed with a heavy pressing force for prevention of the measuring cell from being displaced. However, if the entire measuring cell is pressed with a heavy pressing force, the flow path member is deformed, which may cause the signal obtained by the reflection of the light beam to be unstable.

On the other hand, if the pressing force is of such a degree that an unstable signal will not be generated, there occurs a problem that, at the time of the above-mentioned access, the measuring cell may be displaced, resulting in the signal being changed.

### SUMMARY OF THE INVENTION

The present invention has been made in view of the above-mentioned fact, and provides a measuring cell holding mechanism which prevents the flat face of the measuring cell where the ligand is attached(immobilized) from being displaced at the time of measurement, and can prevent the flow path member from being deformed, and a biosensor comprising this measuring cell holding mechanism.

The measuring cell holding mechanism of a first aspect of the present invention comprises a measuring cell which is configured to include a dielectric block in which a substantially flat face on which a ligand to be attached is formed, and a flow path member which is tightly adhered to the flat face of the dielectric block and forms a flow path between itself and the flat face, and in which a supply port and a discharge port which communicate with the flow path and are opened on the upper side of the flow path member are formed; a dielectric block pressing member which touches and presses said dielectric block from the flow path member side; a flow path member pressing member which presses said flow path member from the side opposite from the side on which the dielectric block is disposed, with a pressing force that is smaller than a pressing force of the dielectric block pressing member; and a base member which receives the pressing force of the dielectric block pressing member and that of the flow path member pressing member.

With the measuring cell holding mechanism of the first aspect, the dielectric block portion of the measuring cell is pressed by the dielectric block pressing means, and the flow path member is pressed by the flow path member pressing means. The dielectric block pressing means directly touches the dielectric block, and presses it from the flow path member side, thus pressing force will not be transmitted to the flow path member. Therefore, the dielectric block can be pressed with such a heavy pressing force that it will not be displaced by the access to a liquid supply member which advances into said supply port from above for supplying a liquid to the flow path, which can prevent the flat face where the ligand is attached, from being displaced at the time of measurement.

On the other hand, the flow path member is pressed with a force of the flow path member pressing means that is smaller than that of the dielectric block pressing means, whereby the deformation is prevented, which allows occurrence of an unstable signal resulting from the deformation to be suppressed.

In the present application, the ligand refers to a high polymer having a physiological activity, and examples thereof include protein, DNA, RNA, saccharide, and the like, but it is not limited to these.

The measuring cell holding mechanism of the first aspect may be adapted to provide the measuring cell holding mechanism of the first aspect, wherein the dielectric block pressing means and the flow path member pressing means are driven from a common drive source.

Thus, if the dielectric block pressing means and the flow path member pressing means are driven from a common drive source, the construction of the drive mechanism can be rendered simple.

In addition, the measuring cell holding mechanism of the first aspect may be adapted to provide the measuring cell holding mechanism of the first aspect, wherein, in the flow path member, a through-hole which penetrates from the top face thereof to the face thereof that is tightly adhered to the dielectric block is formed, and the dielectric block pressing member is inserted into the through-hole to touch the dielectric block.

Thus, a through-hole is formed in the flow path member, and the dielectric block pressing means is inserted into this through-hole to touch the dielectric block, whereby the need for providing the dielectric block with a convex portion for touching is eliminated, and thus the measuring cell can be rendered compact.

The biosensor of the second aspect provides a biosensor, comprising the measuring cell holding mechanism of the first aspect; a light source which irradiates a light beam to the flat face of the measuring cell through the dielectric block; and a light receiving member which receives reflected light of the light beam which has been reflected at the flat face.

According to the biosensor of the second aspect, a measuring cell holding mechanism which can prevent the flat face where the ligand is attached, from being displaced at the time of measurement, and can also prevent the flow path member from being deformed, thus fluctuation of the reflected light resulting from the flat face being displaced is suppressed, and thus accurate measurement can be carried out.

Because the present invention is configured as described above, the flat face of the measuring cell where the ligand is attached can be prevented from being displaced at the time of measurement, and in addition the flow path member can be prevented from being deformed.

### BRIEF DESCRIPTION OF THE DRAWINGS

FIG. 1 is a general perspective side view of a biosensor of the present embodiment;

FIG. 2 is a perspective side view of a sensor stick of the present embodiment;

FIG. 3 is an exploded perspective side view of the sensor stick of the present embodiment;

FIG. 4 is a sectional view of the liquid flow path portion of the sensor stick of the present embodiment;

FIG. 5 is a drawing illustrating the state in which a light beam is irradiated to the measurement region and the reference region of the sensor stick of the present embodiment, respectively;

FIG. 6 is a perspective side view of a holding-down part of the present embodiment;

FIG. 7 is a front view of the holding-down part of the present embodiment;

FIG. 8 is a front view around the location for holding-down by the holding-down part of the present embodiment;

FIG. 9 is a side view around the location for holding-down by the holding-down part of the present embodiment;

FIG. 10 is a schematic drawing for the area around the optical measuring part of the biosensor of the present embodiment;

FIG. 11 is a schematic block diagram of the control section and the peripheral thereof of the present embodiment;

FIG. 12A is a top view illustrating the state in which the dielectric block is held down by a prism holding-down member of the present embodiment;

FIG. 12B is a side view illustrating the state in which the dielectric block is held down by the prism holding-down member of the present embodiment;

FIG. 13 is a drawing illustrating the state in which pipette tips are inserted into the liquid flow path of the present embodiment;

FIG. 14A is a top view illustrating the state in which the dielectric block is held down by the prism holding-down member of a modification of the present embodiment;

FIG. 14B is a side view illustrating the state in which the dielectric block is held down by the prism holding-down member of the modification of the present embodiment;

FIG. 15A is a side view when viewed from the longitudinal direction that illustrates the state in which the dielectric block is held down by the prism holding-down member of another modification of the present embodiment; and

FIG. 15B is a side view when viewed from the shortitudinal direction that illustrates the state in which the dielectric block is held down by the prism holding-down member of another modification of the present embodiment.

### DETAILED DESCRIPTION OF THE INVENTION

Hereinbelow, an embodiment of the present invention will be described with reference to the drawings.

A biosensor 10 of the present embodiment is a so-called surface plasmon sensor which utilizes the surface plasmon resonance occurring at the surface of a metal film for measuring the interaction between a ligand D and an analyte A.

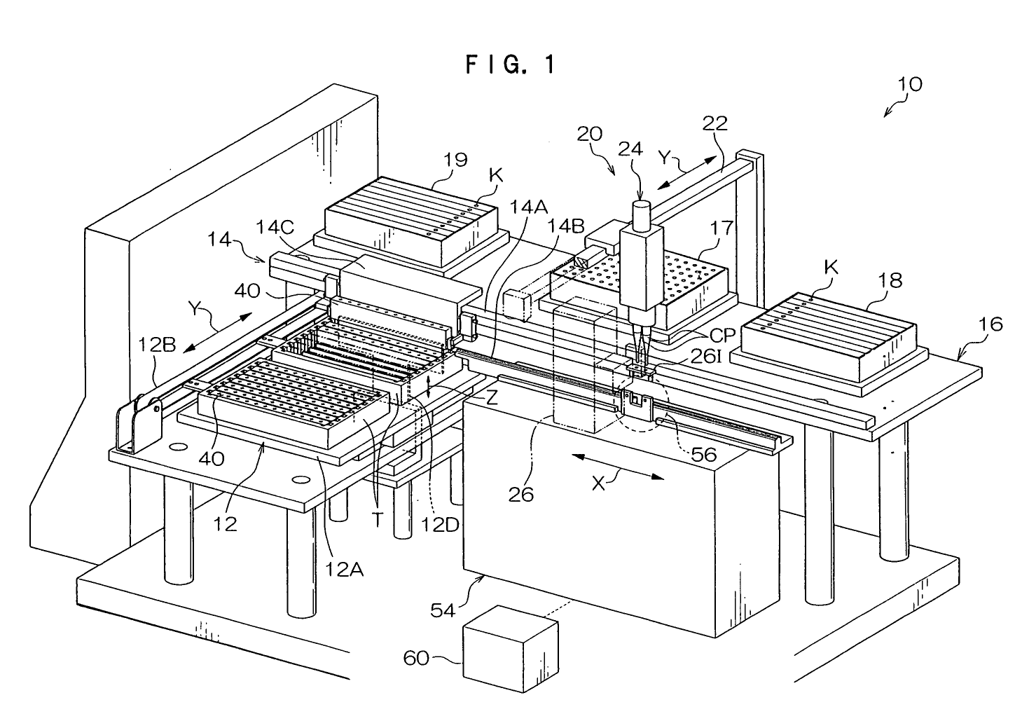

As shown in FIG. 1, the biosensor 10 comprises a tray holding part 12, a transferring part 14, a container platform 16, a liquid supply/discharge part 20, a holding-down part 26, an optical measuring part 54, and a control section 60.

The tray holding part 12 is configured to comprise a platform 12A, and a belt 12B. The platform 12A is mounted to the belt 12B extended in the direction of arrow Y, and can be moved in the direction of arrow Y by running the belt 12B. On the platform 12A, two trays T are placed, being located. The tray T accommodates sensor sticks 40. The sensor stick 40 provides a chip on which the ligand D is attached, and will be described later in detail. Under the platform 12A, a pushing-up mechanism 12D is disposed which pushes up the sensor stick 40 to the position where it is held by a stick holding member 14C later described.

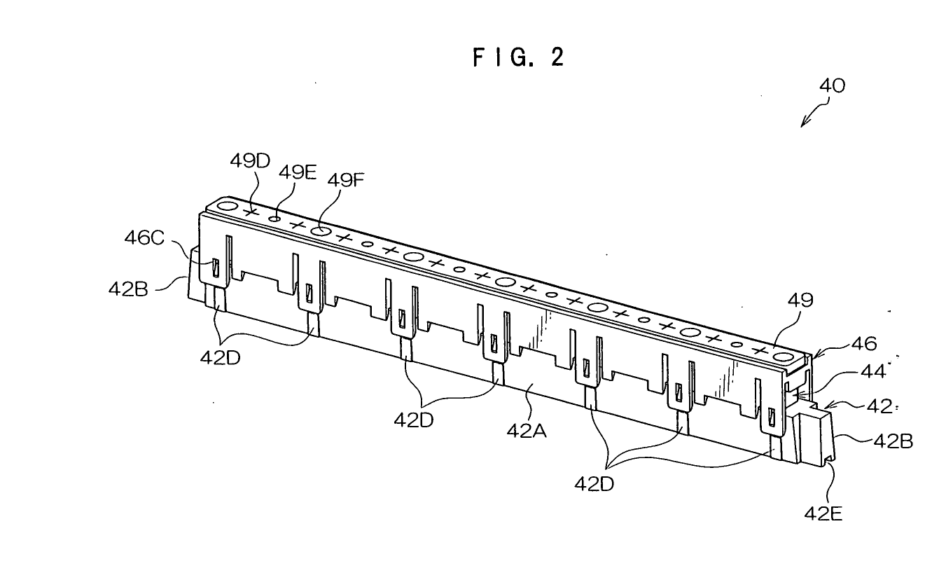

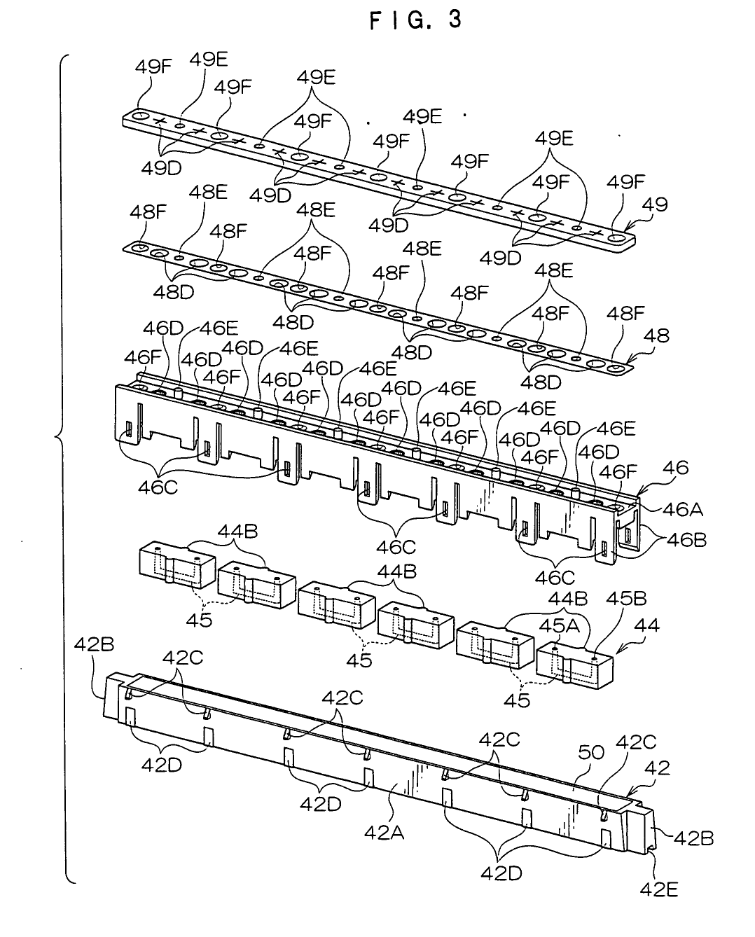

As shown in FIG. 2 and FIG. 3, the sensor stick 40 is made up of a dielectric block 42, a flow path member 44, a holding member 46, an adhesion member 48, and an evaporation prevention member 49.

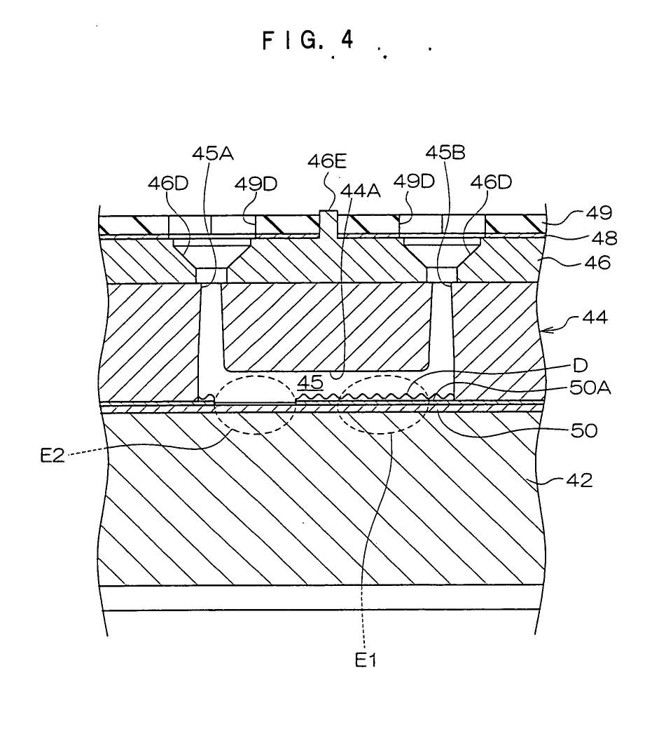

The dielectric block 42 is made up of a transparent resin, or the like, which is transparent to a light beam, comprising a prism part 42A which is formed in the shape of a bar having a trapezoid section, and a to-be-held part 42B at both ends of the prism part 42A that is formed integrally with the prism part 42A. As shown also in FIG. 4, on the top face of the prism part 42A, which is a wider one of the two faces in parallel with each other, a metal film 50 is formed. On this metal film 50, the ligand D which is analyzed with the biosensor 10 is attached. The dielectric block 42 functions as a so-called prism. In measurement with the biosensor 10, a light beam is irradiated to one of the two opposite side faces of the prism part 42A not in parallel with each other, and from the other, the light beam totally reflected at the boundary face of the metal film 50 is emitted.

As shown in FIG. 4, on the surface of the metal film 50, a linker layer 50A is formed. The linker layer 50A is a layer for attaching the ligand D on the metal film 50. On the linker layer 50A, a measurement region (E1) where the ligand D is attached, and reaction between the analyte A and the ligand D occurs, and a reference region (E2) where the ligand D is not attached, and which is for obtaining a reference signal in signal measurement with said measurement region E1 are formed.

This reference region E2 is formed in forming a film as the above-mentioned linker layer 50A. The formation method is, for example, to subject the linker layer 50A to a surface treatment (blocking) for deactivation of the coupling group which couples to the ligand D. Thereby, a half of the linker layer 50A is provided as the measurement region E1, and the remaining half is as the reference region E2. In order to thus deactivate the coupling group, ethanolamine hydrochloride can be used. As another method for forming the reference region E2, an alkyl thiol, for example, instead of carboxymethyl dextran is disposed in the reference region E2, whereby an alkyl group can be disposed on the surface, and because the alkyl group cannot be ligand-coupled by the amino coupling method, the region thus formed can be used as the reference region E2.

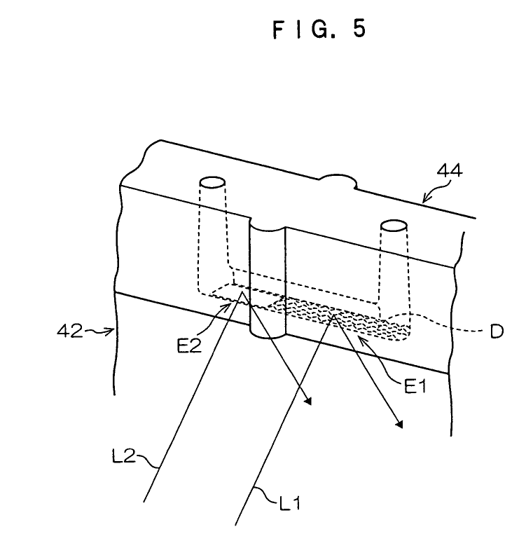

As shown also in FIG. 5, in the portion of the linker layer 50A that is exposed to the liquid flow path 45, other than the reference region E2, the ligand D is attached. In the reference region E2, the ligand D is not attached. To the reference region E2 and the measurement region E1, light beams L2 and L1 are irradiated, respectively. The reference region E2 is a region provided for compensating the data obtained from the measurement region E1 where the ligand D is attached.

On both side faces of the prism part 42A, an engaging convex part 42C which is engaged with the holding member 46, and a vertical convex part 42D which is configured on the extension of an imaginary plane perpendicular to the top face of the prism part 42A are formed in plural places along the lower edge side, respectively. In addition, in the central portion of the bottom face of the dielectric block 42 that is along the longitudinal direction thereof, an engaging groove 42E is formed.

The flow path member 44 is formed as a hexahedron slightly narrower than the dielectric block 42, and as shown in FIG. 3, six flow path members 44 are disposed on the metal film 50 on the dielectric block 42, being separated from one another. In the bottom face of the respective flow path members 44, a flow path groove 44A (see FIG. 4) is formed to communicate into a feed port 45A and a discharge port 45B which are formed in the top face, constituting a liquid flow path 45 with the metal film 50. Thus, for one sensor stick 40, six independent liquid flow paths 45 are provided. On the side wall of the flow path member 44, a convex part 44B to be force fitted into the concave part (not shown) in the inside of the holding member 46 for securing the adherence to the holding member 46 is formed.

It is assumed that, for the liquid flow path 45, a liquid containing protein is supplied, thus it is preferable that, in order to prevent the protein from anchoring to the flow path wall, the material for the flow path member 44 have no non-specific adsorptivity for proteins.

The holding member 46 is formed in a continuous length, being composed of a top plate 46A and two side plates 46B. In the side plate 46B, engaging holes 46C which are engaged with the engaging convex parts 42C of the dielectric block 42 are formed. The holding member 46 is mounted to the dielectric block 42, sandwiching the six flow path members 44 therebetween, with the engaging hole 46C being engaged with the engaging convex part 42C. Thereby, the flow path members 44 are tightly adhered to the dielectric block 42, which forms the liquid flow path 45 between the respective flow path members 44 and the dielectric block 42. In the top plate 46A, a tapered pipette insertion hole 46D which is narrowed down toward the flow path member 44 is formed in the locations opposed to the feed port 45A and the discharge port 45B of the flow path member 44, respectively. In addition, between the two pipette insertion holes 46D which are disposed in the locations opposed to the supply port 45A and the discharge port 45B for one flow path member 44, a locating boss 46E is formed. Further, in the location which is opposed to the spacing between two adjacent flow path members 44 separately disposed, a holding-down hole 46F into which a prism holding-down member 26K later described can be inserted is formed.

To the top face of the holding member 46, the evaporation prevention member 49 is adhered through the adhesion member 48. In the adhesion member 48, a hole 48D for pipette insertion is formed in the location opposed to the pipette insertion hole 46D; in the location opposed to the boss 46E, a locating hole 48E is formed; and in the location opposed to the holding-down hole 46F, a hole 48F is formed. In addition, in the evaporation prevention member 49, a slit 49D, which is a cutout in the shape of a cross, is formed in the location opposed to the pipette insertion hole 46D; in the location opposed to the boss 46E, a locating hole 49E is formed; and in the location opposed to the holding-down hole 46F, a hole 49F is formed. By inserting the boss 46E into the holes 48E and 49E for adhering the evaporation prevention member 49 to the top face of the holding member 46, the unit is configured such that the slit 49D in the evaporation prevention member 49 is opposed to the feed port 45A and the discharge port 45B of the flow path member 44, respectively. When a pipette tip CP is not inserted, the slit 49D covers the feed port 45A, evaporation of the liquid supplied to the liquid flow path 45 is prevented.

As shown in FIG. 1, the transferring part 14 of the biosensor 10 is configured to comprise an upper guide rail 14A, a lower guide rail 14B, and a stick holding member 14C. The upper guide rail 14A and the lower guide rail 14B are horizontally disposed in the direction of arrow X that is perpendicular to the direction of arrow Y, above the tray holding part 12 and the optical measuring part 54. To the upper guide rail 14A, the stick holding member 14C is mounted. The stick holding member 14C can hold the to-be-held part 42B at both ends of the sensor stick 40, and move along the upper guide rail 14A. The engaging groove 42E in the sensor stick 40 held by the stick holding member 14C and the lower guide rail 14B are engaged with each other, and the stick holding member 14C is moved in the direction of arrow X, whereby the sensor stick 40 is transferred to the measuring part 56 above the optical measuring part 54.

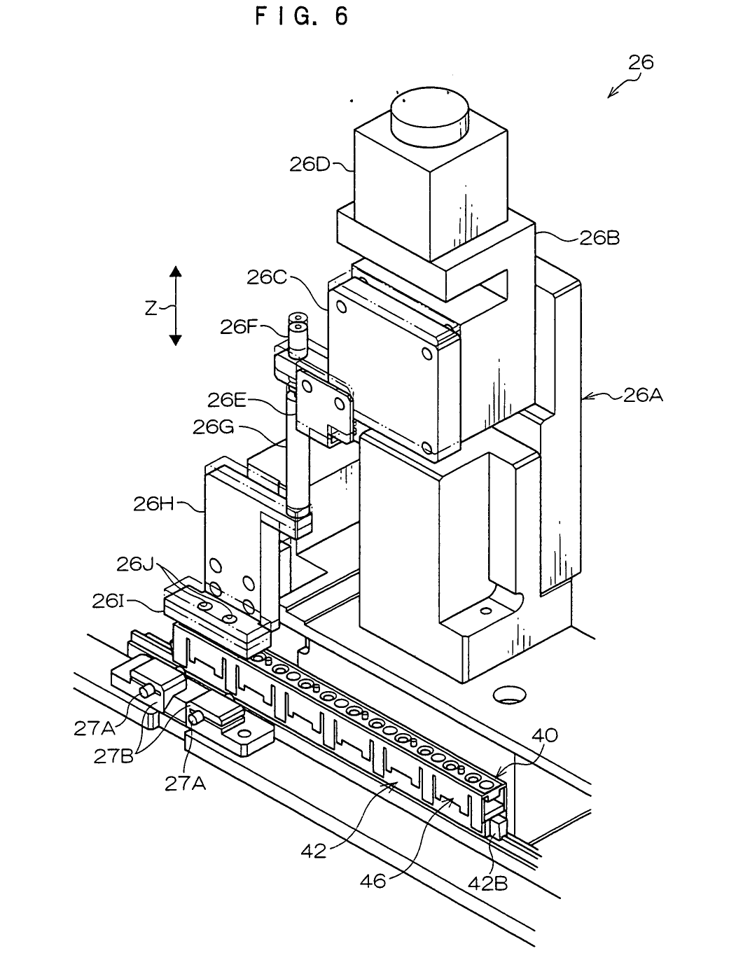

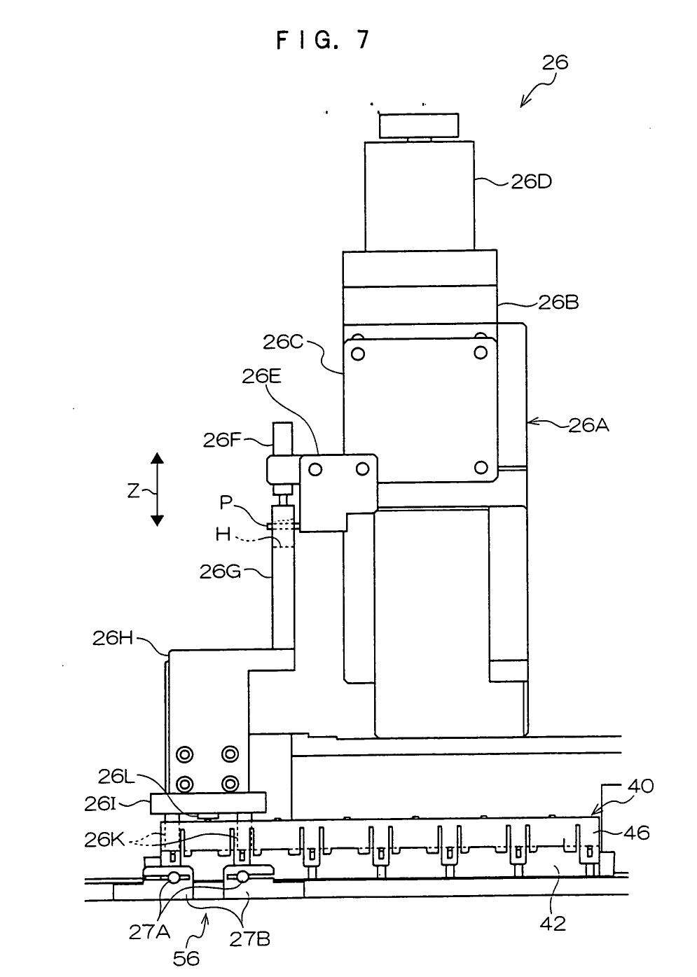

On the side opposite from that of the stick holding member 14C, the holding-down part 26 for holding down the sensor stick 40 at the time of measurement is provided, with the lower guide rail 14B disposed therebetween. As shown in FIG. 6 and FIG. 7, the holding-down part 26 comprises a support part 26A, and to the support part 26A, a stage 26B is mounted. On the side face of the stage 26B, a drive guide 26C is mounted. The drive guide 26C can be moved in the Z direction (the vertical direction) along the side face of the stage 26B by the driving force of a drive motor 26D disposed on the top of the stage 26B. To the drive guide 26C, a holding-down spring 26F is mounted through a coupling member 26E. On the lower side of the holding-down spring 26F, a stick 26G is disposed; on the lower side of the stick 26G, a plate member 26H is mounted; and at the lower portion side face of the plate member 26H, a holding-down plate 26I is mounted.

As shown in FIG. 7, in the upper portion of the stick 26G, a hole H is holed in the horizontal direction, and a pin P which juts out from the coupling member 26E is inserted into the hole H. The hole H is a hole elongated downward such that the pin P is downward movable in the hole H. The stick 26G, the plate member 26H, and the holding-down plate 26I are moved downward, being pressed by the holding-down spring 26F, with the drive guide 26C being lowered. The holding-down spring 26F is set such that, by contracting by a prescribed amount, the prism holding-down member 26K later described presses the dielectric block 42 with a prescribed pressing force. Herein, the prescribed pressing force refers to such a degree of pressing force that it prevents the dielectric block 42 from being displaced even in an insertion and pulling-out operation of the pipette tip CP later described. In addition, the stick 26G, the plate member 26H, and the holding-down plate 26I are lifted by the pin P with the drive guide 26C being raised.

The holding-down plate 26I is in the shape of a rectangular plate, being disposed such that the plate face is opposed to the sensor stick 40 and the longitudinal direction thereof is in parallel with the lower guide rail 14B. In the holding-down plate 26I, two holes 26J into which the pipette tips CP later described can be inserted are formed.

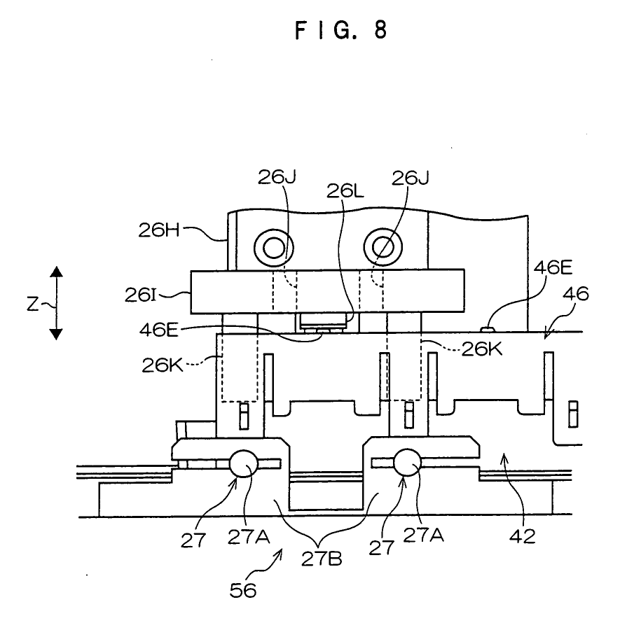

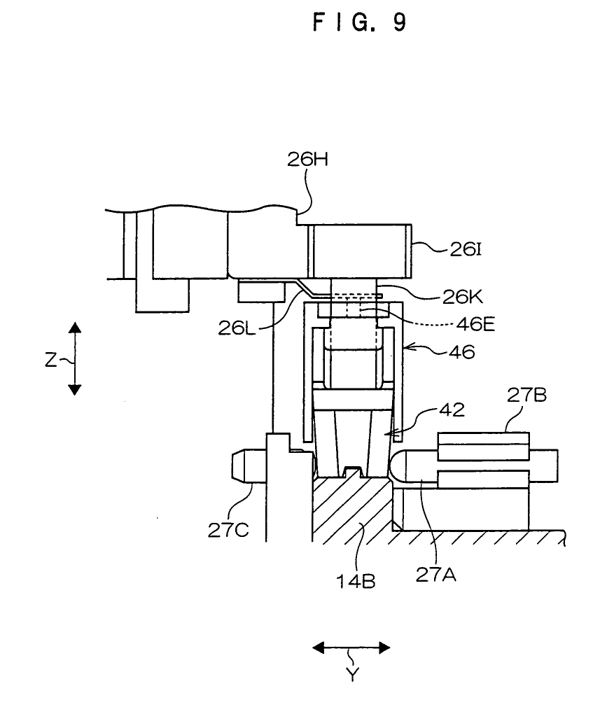

In addition, as shown in FIG. 8, on the lower side of the holding-down plate 26I, the prism holding-down member 26K and the flow path holding-down member 26L are provided. Two prism holding-down members 26K are provided in the locations corresponding to the holding-down holes 46F which are formed in the holding member 46 of the sensor stick 40, being inserted in the holding-down holes 46F, and touching the prism part 42A. As shown in FIG. 9, the flow path holding-down member 26L is made up of a leaf spring which is elastically deformable in the Z direction, the basal part being mounted to the plate member 26H. The leaf spring is set such that, when touches the boss 46E of the flow path holding-down member 26L, it presses the boss 46E with a pressing force smaller than that applied by the holding-down spring.

The pressing force of the prism holding-down member 26K and the flow path holding-down member 26L is received by the lower guide rail 14B.

On the lower side of the measurement part 56, a pinch holding-down member 27 is provided. The pinch holding-down member 27 is configured to comprise a pressing stick 27A which is disposed on the side of the lower guide rail 14B that is opposite from the holding-down part 26 side, a holding member 27B which holds the pressing stick 27A, and a spring part 27C which is disposed on the side opposite from the pressing stick 27A side, with the lower guide rail 14B disposed therebetween. Between the pressing stick 27A and the spring part 27C, the sensor stick 40 is pinched, the movement thereof in the Y direction being restricted.

As shown in FIG. 1, on the container platform 16, an analyte solution plate 17, a recovery liquid stock container 18, and a supply liquid stock container 19 are placed. The analyte solution plate 17 is partitioned in the shape of a matrix for making it possible to stock various analyte solutions. The recovery liquid stock container 18 is made up of a plurality of recovery containers, and in the respective recovery containers, an opening K for allowing a later described pipette tip CP to be inserted thereinto is formed. The supply liquid stock container 19 is made up of a plurality of stock containers, in each of which an opening K for allowing the pipette tip CP to be inserted thereinto is formed in the same manner as in the recovery container.

The liquid supply/discharge part 20 is configured to comprise the upper guide rail 14A, the lower guide rail 14B, a traversing rail 22 suspended above these in the direction of arrow Y, and a head 24. The traversing rail 22 can be moved in the direction of arrow X by a drive mechanism (not shown). In addition, the head 24 is mounted to the traversing rail 22, and can be moved in the direction of arrow Y. In addition, the head 24 can be moved in the vertical direction (in the direction of arrow Z) by a drive mechanism (not shown) direction. To the head 24, two pipette tips CP are mounted.

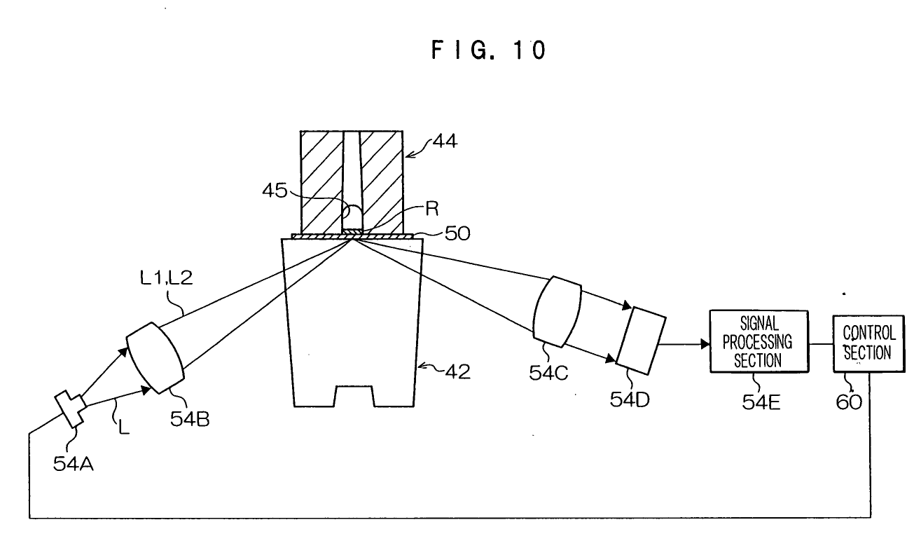

As shown in FIG. 10, the optical measuring part 54 is configured to comprise a light source 54A, a first optical system 54B, a second optical system 54C, a light receiving section 54D, and a signal processing section 54E. From the light source 54A, a light beam L in the diverging state is emitted. The light beam L is changed into two light beams L1 and L2 through the first optical system 54B, being irradiated to the measurement region E1 and the reference region E2 of the dielectric block 42 disposed in the measuring part 56 (see FIG. 5). In the measurement region E1 and the reference region E2, the light beams L1 and L2 are irradiated, including various incident angle components with respect to the boundary between the metal film 50 and the dielectric block 42, and at an angle of the total reflection angle or larger. The light beams L1 and L2 are totally reflected at the boundary between the dielectric block 42 and the metal film 50. The totally reflected light beams L1 and L2 are reflected with various reflection angle components. These totally reflected light beams L1 and L2 are received by the light receiving section 54D through the second optical system 54C to be photoelectrically converted, respectively, and light detection signals are outputted to the signal processing section 54E. In the signal processing section 54E, a prescribed processing is carried out on the basis of the light detection signals inputted, and the data for total reflection attenuation angle (which is hereinafter to be called the “total reflection attenuation angle data”) for the measurement region E1 and the reference region E2 is determined. This total reflection attenuation angle data is outputted to the control section 60.

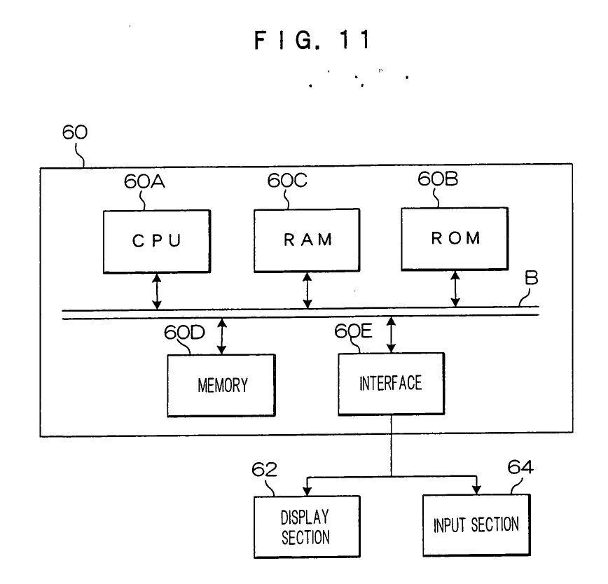

The control section 60 has the function for controlling the entire biosensor 10, and as shown in FIG. 10, is connected to the light source 54A, the signal processing section 54E, and the drive system of the biosensor 10 (not shown). As shown in FIG. 11, the control section 60 has a CPU 60A, an ROM 60B, an RAM 60C, a memory 60D, and an interface 60E which are mutually connected through a bus B, being connected to a display section 62 which displays various pieces of information, and an input section 64 for inputting various instructions and various pieces of information.

In the memory 60D, various programs for controlling the biosensor 10 and various data are recorded.

Next, the procedure for fixing the sensor stick in the measurement part 56 will be described.

On the platform 12A of the biosensor 10, a tray containing the sensor stick 40 in which the ligand D is attached, and which is filled with a conservation liquid C in the liquid flow path 45 is set. In addition, in the analyte solution plate 17 and the supply liquid stock container 19, a prescribed analyte solution and a supply liquid (a buffer liquid, a cleaning liquid, and the like) are set, respectively.

First, by the pushing-up mechanism 12D, one sensor stick 40 is pushed up to the level of the stick holding member 14C, and held by the stick holding member 14C. Then, the stick holding member 14C holding the sensor stick 40 is moved along the lower guide rail 14B for transferring the sensor stick 40 to the measuring part 56.

The stick holding member 14C is stopped in a prescribed position in the measurement part 56, and the side faces of the prism part 42A of the sensor stick 40 are pinched by the pressing stick 27A and the spring part 27C of the pinch holding-down member 27.

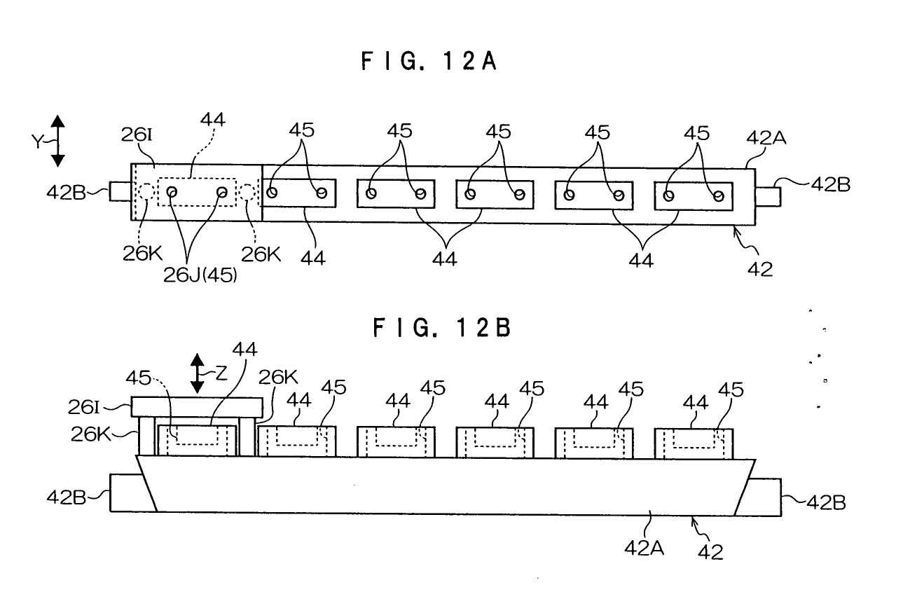

In addition, the drive guide 26C of the holding-down part 26 is moved downward, and the stick 26G, the plate member 26H, and the holding-down plate 26I are lowered, being pressed by the holding-down spring 26F. Thereby, the prism holding-down member 26K is inserted into the holding-down hole 46F, being touched the prism part 42A as shown in FIG. 12B. At this time, as shown in FIG. 12A, the holes 26J are disposed in the positions where they are aligned with the liquid flow path 45. In FIG. 12A and FIG. 12B, drawing of the members constituting the sensor stick 40 other than the dielectric block 42 and the flow path member 44 is omitted.

The drive guide 26C is moved downward in the Z direction such that the holding-down spring 26F is contracted by a preset prescribed amount, and stopped. Thereby, the dielectric block 42 is fixed, being pressed by the prism holding-down member 26K with a prescribed force. In addition, the flow path member 44 is pressed by the flow path holding-down member 26L through the holding member 46 with a prescribed force. The pressing force applied to the flow path member 44 is set smaller than that to the dielectric block 42. For example, the holding-down pressure by the prism holding-down member 26K can be set at 2 N/mm², and the holding-down pressure by the flow path holding-down member 26L can be set at 0.34 N/mm².

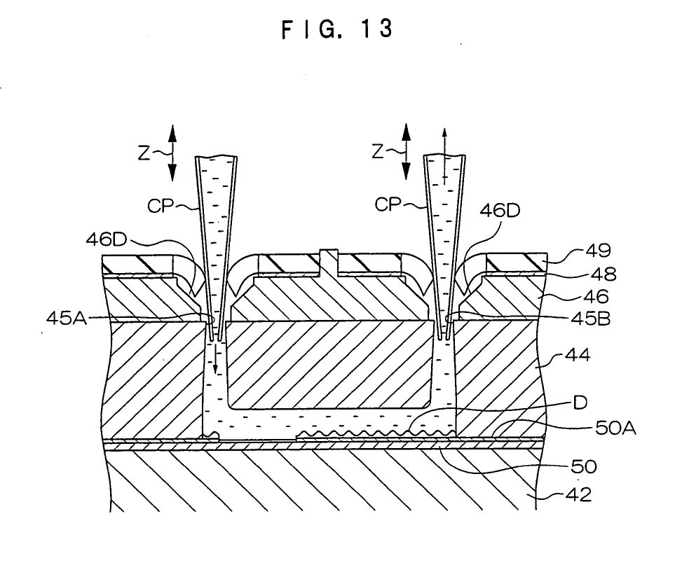

In supplying a liquid, such as the analyte solution, or the like, to or recovering (discarding) the supplied liquid from the sensor stick 40 fixed in the above-mentioned manner, the pipette tip CP is inserted into the liquid flow path 45 in the flow path member 44 from above or pulled out through the pipette insertion hole 46D as shown in FIG. 13. At this time, the pipette tip CP is contacted with the holding member 46 and the flow path member 44, applying a force thereto, however, because the flow path member 44 has been pressed downward to be fixed by the flow path holding-down member 26L, it is prevented from being displaced.

In addition, the dielectric block 42 is pressed downward to be fixed by the block holding-down member 26K, and the pressing force is larger than the pressing force of the flow path holding-down member 26L, being of such a degree that the dielectric block 42 will not be displaced even with the operation of inserting and pulling-out the pipette tip CP, thus, even if the pipette tip CP is inserted and pulled out during the measurement with the light beam L being irradiated, the dielectric block 42 can be prevented from being displaced.

In addition, because the flow path member 44 is pressed with a pressing force smaller than a pressing force that applied to the dielectric block 42, troubles, such as a signal fluctuation in the drift mode being caused in the measurement resulting from the flow path member 44 being pressed with a heavy force, and the like, can be prevented.

In the present embodiment, the prism holding-down member 26K is disposed in the spacing provided between adjacent flow path members 44, however, the prism holding-down member may be disposed in any other appropriate location.

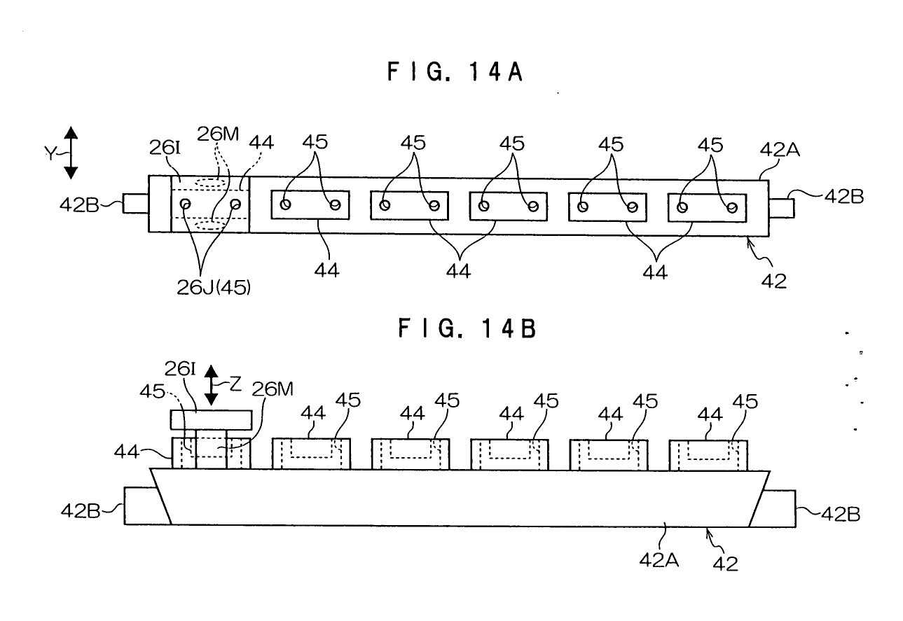

For example, as shown in FIG. 14A and 14B, prism holding-down members 26M which are disposed in the Y direction, i.e., the shortitudinal direction, of the dielectric block 42, as if they stepped over the flow path member 44 may be adopted. In this case, in the locations in the top face of the holding member 46 that correspond to the prism holding-down members 26M, holes for inserting the prism holding-down member 26M thereinto are holed.

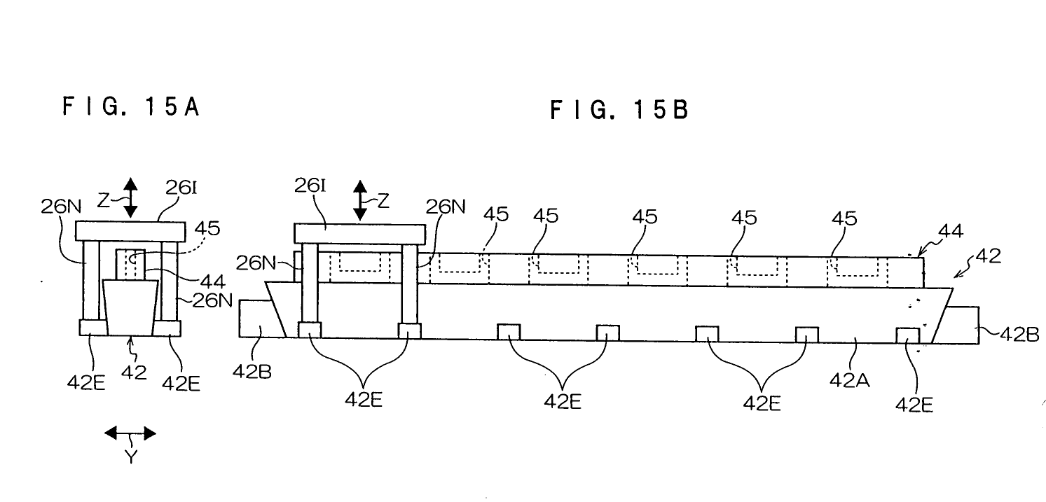

In addition, in a case where it is difficult to provide a space on the top face of the dielectric block 42 for allowing the prism holding-down member to touch, such as that when six liquid flow paths 45 are formed in a single flow path member 44, or the like, holding-down member catching parts 42E jutting out in the Y direction of the dielectric block 42 may be provided at the side faces of the prism part 42A as shown in FIG. 15A and 15B for adapting the prism holding-down member to provide a prism holding-down member 26N which presses the top faces of the holding-down member catching parts 42E from above.

In the present embodiment, as one example of the biosensor, the surface plasmon sensor has been described, however, the present invention can be applied to the leakage mode sensor as a biosensor utilizing the total reflection attenuation. The leakage mode detector is made up of a dielectric, and a thin film constituted by a clad layer and a light guiding layer laminated thereon in this order, one face of this thin film providing a sensor face, and the other face a light incident face. When light is irradiated on the light incident face so as to meet the total reflection conditions, a part thereof permeates said clad layer to be introduced into said light guiding layer. And, when the wave-guiding mode is excited in this light guiding layer, the reflected light on said light incident face is greatly attenuated. The incident angle at which the wave-guiding mode is excited varies depending upon the refractive index for the medium on the sensor face as with the surface plasmon resonance angle. By detecting the attenuation of this reflected light, the reaction on said sensor face can be measured.

What is claimed is:

1. A measuring cell holding mechanism, comprising:
a measuring cell which is configured to include a dielectric block in which a substantially flat face on which a ligand to be attached is formed, and a flow path member which is tightly adhered to the flat face of the dielectric block and forms a flow path between itself and the flat face, and in which a supply port and a discharge port which communicate with the flow path and are opened on the upper side of the flow path member are formed;
a dielectric block pressing member which touches and presses said dielectric block from the flow path member side;
a flow path member pressing member which presses said flow path member from the side opposite from the side on which the dielectric block is disposed, with a pressing force that is smaller than a pressing force of the dielectric block pressing member; and
a base member which receives the pressing force of the dielectric block pressing member and that of the flow path member pressing member.

2. The measuring cell holding mechanism of claim 1, wherein the dielectric block pressing member and said flow path member pressing member are driven from a common drive source.

3. The measuring cell holding mechanism of claim 1, wherein:
in the flow path member, a through-hole which penetrates from the top face thereof to the face thereof that is tightly adhered to the dielectric block is formed;
and the dielectric block pressing member is inserted into said through-hole to touch the dielectric block.

4. The measuring cell holding mechanism of claim 2, wherein;
in the flow path member, a through-hole which penetrates from the top face thereof to the face thereof that is tightly adhered to the dielectric block is formed;
and the dielectric block pressing member is inserted into the through-hole to touch the dielectric block.

5. The measuring cell holding mechanism of claim 3, wherein:
the through-hole is formed in two places with said liquid flew path disposed therebetween;
and two of the dielectric block pressing members are inserted into said two through-holes, respectively.

6. The measuring cell holding mechanism of claim 4, wherein:
the through-hole is formed in two places with said liquid flew path disposed therebetween;
and two of the dielectric block pressing members are inserted into said two through-holes, respectively.

7. A biosensor, comprising:
a measuring cell holding mechanism, comprising a measuring cell which is configured to include a dielectric block in which a substantially flat face on which a ligand to be attached is formed, and a flow path member which is tightly adhered to the flat face of the dielectric block and forms a flow path between itself and the flat face, and in which a supply port and a discharge port which communicate with the flow path and are opened on the upper side of the flow path member are formed,
a dielectric block pressing member which touches and presses the dielectric block from the flow path member side,
a flow path member pressing member which presses the flow path member from the side opposite from the side on which the dielectric block is disposed, with a pressing force that is smaller than a pressing force of said dielectric block pressing member, and
a base member which receives the pressing force of the dielectric block pressing member and that of the flow path member pressing member;
a light source which irradiates a light beam to said flat face of said measuring cell through said dielectric block; and
a light receiving member which receives reflected light of the light beam which has been reflected at the flat face.
